(19) United States
(12) Patent Application Publication
(10) Pub. No.: US 2026/0348018 A1
(43) Pub. Date: Nov. 5, 2026

(54) COMPRESSIVE PECVD FILMS FOR SUBSTRATE BOW COMPENSATION

(71) Applicant: Applied Materials, Inc., Santa Clara, CA (US)

(72) Inventors: GING-JI WANG, Mountain View, CA (US); SANG JAE PARK, Santa Clara, CA (US); HIRAL TAILOR, Portland, OR (US); ANNAMALAI LAKSHMANAN, Fremont, CA (US); DONGQING YANG, Pleasanton, CA (US); XINHAI HAN, Palo Alto, CA (US)

(21) Appl. No.: 19/199,222

(22) Filed: May 5, 2025

(51) Int. Cl. C23C 16/505; C23C 16/34; C23C 16/52

(52) U.S. Cl. CPC C23C 16/505; C23C 16/345; C23C 16/52

(57) ABSTRACT

Embodiments described herein relate to a method that includes initiating a deposition process to deposit a layer on a surface of a substrate with a first bow, where the deposition process is a plasma enhanced chemical vapor deposition (PECVD) process that includes forming a plasma with a first RF input frequency and a second RF input frequency. In an embodiment, the method further comprises continuing the deposition process until the layer reaches a target thickness. In an embodiment, the layer with the target thickness induces a stress in the substrate that changes the first bow to a second bow that is smaller than the first bow.

### BACKGROUND

### 1) Field

Embodiments relate to the field of semiconductor manufacturing and, in particular, processes for depositing compressive films for reducing substrate bow.

### 2) Description of Related Art

Some semiconductor based products rely on the stacking of multiple thin films. Memory devices (e.g., 3D NAND) are one such device. For example, the memory device may include many alternating insulating layers and conductive layers. The stress from the thin films results in warpage or bowing of the underlying substrate (e.g., a semiconductor wafer). As the number of layers increase, the resulting bow in the substrate becomes problematic. In some instances, the bow can become so large that subsequent manufacturing becomes difficult or impossible. For example, the bow may result in the substrate not being able to be chucked to an electrostatic chuck for processing, or the bow may result in significant processing nonuniformity.

Accordingly, attempts to improve warpage and/or bowing have been proposed. One solution is to provide backside layers on the substrate that induce an opposing stress on the substrate. Ideally, the opposing stress will substantially cancel the stress applied by the device side layers. However, as stresses continue to increase due to the inclusion of more layers, the backside layer is not able to fully counteract the stress. This is because the backside layer cannot be continually increased in thickness due to cracking and/or delamination.

### SUMMARY

Embodiments described herein relate to a method that includes initiating a deposition process to deposit a layer on a surface of a substrate with a first bow, where the deposition process is a plasma enhanced chemical vapor deposition (PECVD) process that includes forming a plasma with a first RF input frequency and a second RF input frequency. In an embodiment, the method further comprises continuing the deposition process until the layer reaches a target thickness. In an embodiment, the layer with the target thickness induces a stress in the substrate that changes the first bow to a second bow that is smaller than the first bow.

Embodiments described herein relate to a method that includes measuring a bow of a substrate, and calculating a thickness of a layer that is to be deposited on the substrate that reduces the bow to a desired threshold. In an embodiment, the method further includes initiating a deposition process to deposit the layer on a surface of the substrate with a plasma enhanced chemical vapor deposition (PECVD) process. In an embodiment, the PECVD process includes forming a plasma with a first RF input frequency and a second RF input frequency. In an embodiment, the method further includes continuing the deposition process until the layer reaches the thickness.

Embodiments described herein relate to a method that includes depositing one or more device layers on a first surface of a substrate, where the one or more device layers induce a tensile stress on the substrate that produces a substrate bow. In an embodiment, the method further includes depositing a compressive silicon nitride layer on a second surface of the substrate with a plasma enhanced chemical vapor deposition (PECVD) process that includes forming a plasma with a first RF input frequency and a second RF input frequency. In an embodiment, the compressive silicon nitride layer induces a compressive stress on the substrate that reduces the substrate bow.

### BRIEF DESCRIPTION OF THE DRAWINGS

FIG. 1A is a cross-sectional illustration of a substrate that has a bow, in accordance with an embodiment.

FIG. 1B is a cross-sectional illustration of a substrate that has a backside compressive layer for bow reduction, in accordance with an embodiment.

FIG. 2 is a cross-sectional illustration of a plasma enhanced chemical vapor deposition (PECVD) chamber with a high frequency RF source and a low frequency RF source, in accordance with an embodiment.

FIG. 3A is a cross-sectional illustration of a substrate with a backside compressive layer for bow reduction, in accordance with an embodiment.

FIG. 3B is a cross-sectional illustration of a substrate with a backside compressive layer with a gradient, in accordance with an embodiment.

FIG. 4 is a plan view schematic illustration of a processing tool that may be used to deposit a backside compressive layer on a substrate for bow reduction with a PECVD chamber, in accordance with an embodiment.

FIG. 5 is a flow diagram that depicts a process for forming a backside compressive layer on a substrate for bow reduction, in accordance with an embodiment.

FIG. 6 is a flow diagram that depicts a process for forming a backside compressive layer with a desired thickness in order to minimize bow of a substrate, in accordance with an embodiment.

FIG. 7 illustrates a block diagram of an exemplary computer system that may be used in conjunction with a processing tool, in accordance with an embodiment.

### DETAILED DESCRIPTION

Embodiments described herein include apparatuses and processes for depositing compressive films for reducing substrate bow. Numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, the presence of wafer bow can result in manufacturing difficulties. For example, extreme wafer bow may make it difficult (or impossible) to chuck the wafer with an electrostatic chuck. Additionally, wafer bow may make process uniformity across the wafer more difficult. That is, deposition thicknesses of a given layer may not be uniform across the surface of the wafer. For this reason, attempts have been made to provide wafer bow and/or warpage mitigation. One solution for providing wafer bow and/or warpage mitigation is through the use of a backside bow reduction layer.

The backside bow reduction layer is typically engineered to induce a stress into the substrate that is opposite from the stress applied by device layers formed on the opposing surface of the substrate. However, the stress applied by the device layers continues to increase as the layer count grows. This is problematic since the backside bow reduction layer cannot continue to grow in thickness to negate the additional magnitude of the induced stress. It has been shown that as the backside bow reduction layer increases beyond a certain thickness, the backside bow reduction layer begins to crack and/or delaminate from the substrate. As such, the desired amount of compensating stress from the backside bow reduction layer cannot be induced into the substrate to negate the stress applied by the device layers on the opposing surface.

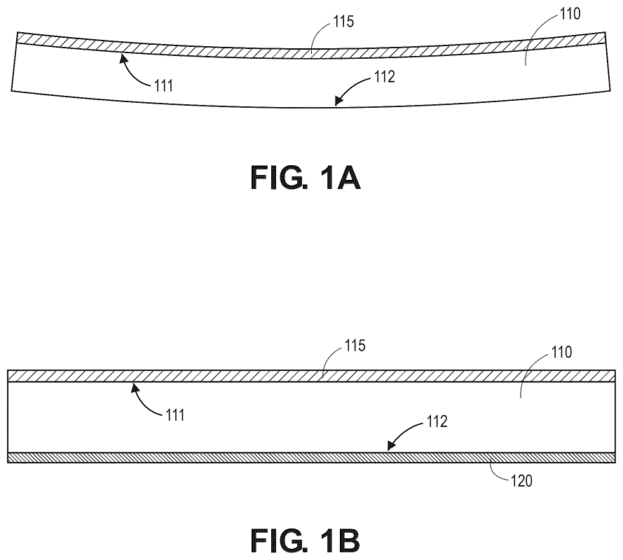

An example of a bowed substrate 110 is shown in FIG. 1A. FIG. 1A is a cross-sectional illustration of a substrate 110 with a bow. The substrate 110 may comprise a semiconductor substrate, such as a silicon wafer or any other type of wafer. The substrate 110 may have a first surface 111 and a second surface 112. As shown, the surfaces 111 and 112 are bowed. The bow of the substrate 110 may be the result of one or more device layers 115 that are formed over the first surface 111. In some instances, the device layers 115 may comprise alternating insulating and conductive layers (not individually shown in FIG. 1A). In FIG. 1A, the bow of the substrate 110 is shown as a dished bow (e.g., with a tensile stress applied to the first surface 111 by the device layers 115). However, the bow of the substrate 110 may also be in the opposite direction (e.g., with a compressive stress applied to the first surface 111 by the device layers).

FIG. 1B is a cross-sectional illustration of the substrate 110 after a backside bow reduction layer 120 is provided over the second surface 112 of the substrate 110. The bow reduction layer 120 may comprise a stress that is opposite from the stress applied by the device layers in order to counteract the bow in the substrate 110. For example, the bow reduction layer 120 may have a compressive stress in order to substantially balance the tensile stress induced by the device layers 115.

In the illustration of FIG. 1B, the bow reduction layer 120 has substantially eliminated the bow of the substrate 110. However, when the thickness of the bow reduction layer 120 increases past a desired level, the bow reduction layer 120 may develop cracks and/or delaminate from the substrate 110. For example, it has been shown that a thickness of the bow reduction layer 120 of approximately 1.0 μm or higher will result in cracking when applied to a semiconductor wafer. Since thicker bow reduction layers 120 are able to induce more stress into the substrate 110, limiting the thickness of the bow reduction layer 120 limits the amount of bow mitigation that is available to the substrate 110. This becomes problematic as the number of device layers 115 continues to increase with advancing technologies.

Currently, the magnitude of the compressive stress that can be generated in a bow reduction layer 120 that comprises silicon nitride is about 2.0 GPa or less. Typically, such silicon nitride bow reduction layers 120 are deposited on the substrate 110 with a physical vapor deposition (PVD) process. In some instances, a curing process (e.g., an ultraviolet (UV) cure) may also be included to increase the magnitude of the compressive stress. However, optimization of the PVD process and/or the curing process is limited, and it is exceedingly difficult to increase the magnitude of the compressive stress.

Accordingly, embodiments disclosed herein may deposit the backside bow reduction layer with an alternative process. For example, the bow reduction layer may be deposited with a plasma enhanced chemical vapor deposition (PECVD) process. In a particular embodiment, the PECVD process May comprise a low frequency RF plasma source and a high frequency RF plasma source. The combination of a low frequency RF plasma source and a high frequency RF plasma source allows for improved tunability of the plasma in order to enable an increase in the magnitude of the stress generated in the bow reduction layer.

In an embodiment, the high frequency plasma source may influence plasma density characteristics, and the low frequency plasma source may influence voltages and/or ion energies. That is, the low frequency plasma source may be tuned to generate high ion energies so that collisions of the ions with the substrate and bow reduction layer are higher energy and lead to an increase in the compressive stress. Additional parameters, such as one or more of temperature of the substrate, pressure, processing gas flow rates, spacing between the electrode and heater, and/or the like may also be used in order to increase the magnitude of stress in the bow reduction layer. In some embodiments, the compressive stress may be approximately −2.0 GPa or more (that is, the magnitude of the compressive stress may be 2.0 GPa or higher), or approximately −3.0 GPa or more (that is, the magnitude of the compressive stress may be 3.0 GPa or more).

Since the magnitude of the compressive stress is increased, the thickness of the bow reduction layer does not need to be as large to counteract the tensile stress induced by the device layers on the opposing surface of the substrate. This provides greater margin for bow reduction and enables the deposition of more device layers on the device side of the substrate. Accordingly, device scaling can continue when bow mitigation layers with increased magnitudes of compressive stress are used.

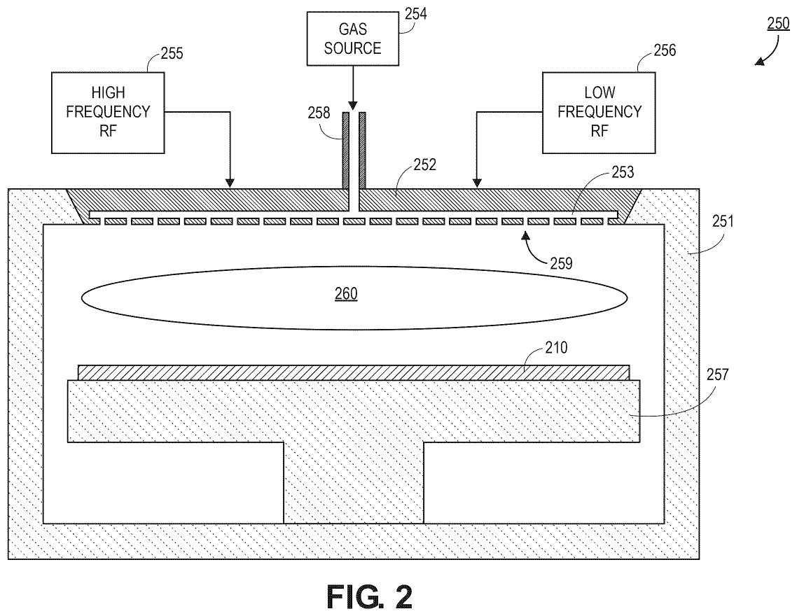

Referring now to FIG. 2, a cross-sectional illustration of a processing tool 250 is shown, in accordance with an embodiment. In an embodiment, the processing tool 250 may comprise a PECVD deposition tool that can be used to deposit a bow reduction layer on the backside surface of a substrate. In an embodiment, the tool 250 may comprise a chamber 251. In an embodiment, the chamber 251 is suitable for supporting low pressure environments (e.g., 20 torr or less, 10 torr or less, 5 torr or less, or 2 torr or less). For example, a vacuum pump and/or exhaust (not shown) may be fluidly coupled to an interior of the chamber 251 in order to reduce a pressure of the interior of the chamber 251.

In an embodiment, the chamber 251 may comprise a pedestal 257 that supports a substrate 210. The pedestal 257 may comprise a chucking feature (e.g., an electrostatic chuck) in order to secure the substrate 210 to the pedestal 257. In an embodiment, the pedestal 257 may include a heater in order to control a temperature of the substrate 210 during processing. For example, the heater may heat the substrate to approximately 400° C. or higher. In an embodiment, the pedestal 257 may also rotate to provide a more uniform processing outcome.

In an embodiment, a lid 252 may seal a portion of the chamber 251. The lid 252 may comprise an electrode for propagating power into the chamber 251. In a particular embodiment, a pair of RF power sources may be coupled to the chamber 251. For example, a high frequency RF source 255 and a low frequency RF source 256 may be coupled to the lid 252. Though, in other embodiments, the high frequency RF source 255 and the low frequency RF source 256 may be coupled to different electrodes within the chamber 251. For example, one RF source may be coupled to an electrode in the lid 252, and the other RF source may be coupled to an electrode in the pedestal 257.

The use of a high frequency RF source 255 and a low frequency RF source 256 allows for greater control of the deposition conditions in order to provide a backside bow reduction film that has a higher compressive stress compared to existing compressive layers or films. For example, the high frequency RF source 255 may enable the formation of high density plasmas 260, and the low frequency RF source 256 may be used to tune voltages and/or ion energies. As such, the ions can be accelerated to the surface of the substrate 210 so that impacts have more energy. This can drive a compression of the film and lead to higher induced compressive stress.

In an embodiment, the high frequency RF source 255 may have a frequency that is approximately 20 MHz or higher, and the low frequency RF source 256 may have a frequency that is 500 kHz or lower. In an embodiment, the high frequency RF source 255 may have a power that is between approximately 100 W and approximately 1,500 W, and the low frequency RF source 256 may have a power that is between approximately 100 W and approximately 300 W.

In addition to better control of the plasma 260 properties, other tool 250 and/or processing conditions may be set to produce increased compressive stresses in the bow reduction layer. In one embodiment, pressure may be set low (e.g., 6.0 torr or less) so that the mean free path is longer for the ions. This leads to more energy for the ions and increases the ion bombardment force. Increasing the ion bombardment force may lead to increased compressive stress in the bow reduction layer. In another embodiment, the spacing between the lid and the pedestal may be decreased. Decreasing this spacing may lead to a stronger electric field. The stronger electric field increases acceleration of the ions, which also leads to increased compressive stress in the bow reduction layer. In some embodiments, the spacing may be approximately 1,000 mil or less, approximately 650 mil or less, or approximately 300 mil or less.

In an embodiment, the lid 252 may also comprise a gas distribution feature 253 that spreads gas throughout the chamber 251. For example, a gas source 254 (which may comprise one or more different source gasses) may be fluidically coupled to the lid 252 by a gas line 258. The gas may be distributed by the gas distribution feature 253 (e.g., a plenum or any other gas distribution architecture) and flow from the lid 252 into the interior of the chamber 251 through holes 259 in a bottom of the lid 252. In an embodiment, any suitable gasses may be flowed into the chamber 251 to provide a bow reduction layer with a desired composition. For example, one or more of NH₃, N₂, Ar, or SiH₄ may be flowed into the chamber 251 in order to produce a compressive silicon nitride layer. Though, other gasses may be used to form other compressive layers, such as boron nitride, silicon boron nitride, carbon based layers, or the like.

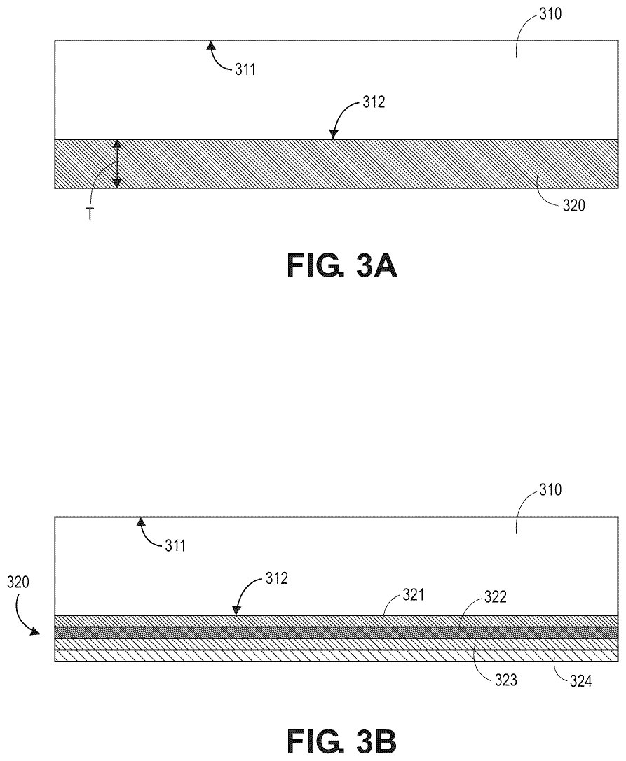

Referring now to FIGS. 3A and 3B, a pair of cross-sectional illustrations depicting a substrates 310 that include a bow reduction layer 320 is shown, in accordance with different embodiments. In the illustrated embodiments, a portion of the substrate 310 is shown, in accordance with an embodiment. The substrate 310 may comprise a semiconductor substrate. The semiconductor substrate may be a silicon wafer, a III-V semiconductor wafer, or the like. The substrate 310 may have any suitable form factor. For example, the form factor may include a 200 mm wafer, a 300 mm wafer, a 400 mm wafer, or the like. In an embodiment, the substrate 310 has a first surface 311 and a second surface 312. The first surface 311 may be the surface on which devices are formed. For example, one or more device layers (not shown) may be formed on the first surface 311. In some embodiments, one or more of the device layers are formed prior to the formation of a bow reduction layer 320 on the second surface 312. In other embodiments, one or more of the device layers are formed after the formation of the bow reduction layer 320 on the second surface 312.

Referring now to FIG. 3A, a cross-sectional illustration of a substrate 310 with a bow reduction layer 320 is shown, in accordance with an embodiment. In an embodiment, the bow reduction layer 320 may be a layer or film that has a compressive stress. For example, bonds between some atoms of the bow reduction layer may be compressed to provide a generally compressive state to the bow reduction layer 320. The bow reduction layer 320 may comprise a silicon nitride material. In other embodiments, the bow reduction layer 320 may comprise other material compositions that are capable of being deposited in a compressively stressed state. For example, the bow reduction layer 320 may comprise a boron nitride composition, a silicon boron nitride composition, a carbon based composition, or the like.

As noted herein, the use of a PECVD process with both a high frequency RF source and a low frequency RF source may allow for the generation of compressive bow reduction layers 320 that have high compressive stress magnitudes. For example, the magnitude of the compressive stress in the bow reduction layer 320 may be approximately 2.0 GPa or higher or approximately 3.0 GPa or higher. The control of processing conditions, such as pressure, temperature, electrode spacing, RF power, and/or the like, may also enable higher compressive stress magnitudes in the bow reduction layer 320.

The ability to form higher compressive stress magnitudes within the bow reduction layer 320 allows for greater amounts of bow correction per unit thickness of the bow reduction layer 320 compared to existing films (which typically have a maximum magnitude of compressive stress that is approximately 2.0 GPa). The backside bow reduction layers 320 may be limited to certain thicknesses T since they begin cracking and/or delaminating after a certain thickness of about 1.0 μm. As such, the increase in the magnitude of the compressive stress in the bow reduction layer 320 allows for a higher amount of total bow reduction for the substrate 310. Since the total amount of bow reduction is increased, additional device layers may be formed over the first surface 311 without increasing the manufacturing complexity.

Referring now to FIG. 3B, a cross-sectional illustration of a substrate 310 with a backside bow reduction layer 320 is shown, in accordance with an additional embodiment. In an embodiment, the bow reduction layer 320 of FIG. 3B is similar to the bow reduction layer 320 in FIG. 3A except that the bow reduction layer 320 in FIG. 3B is formed with a gradient. For example, the bow reduction layer 320 may comprise a plurality of sub-layers 321-324. Though, any number of sub-layers may be used. In an embodiment, each sub-layer 321-324 may have a different composition (e.g., different stoichiometric ratio of elements) and/or different compressive stress magnitudes. While shown as discrete sub-layers 321-324 in FIG. 3B, other embodiments may include a substantially continuous gradient.

The use of a composition and/or stress magnitude gradient may be beneficial for tuning how the stress is induced into the substrate 310 and/or for improving the adhesion between the substrate 310 and the bow reduction layer 320. For example, the sub-layer 321 may be tuned to have a slightly lower magnitude of compressive stress in order to provide better adhesion to the substrate 310, and then the subsequent sub-layers 322-324 may increase the magnitude of the compressive stress.

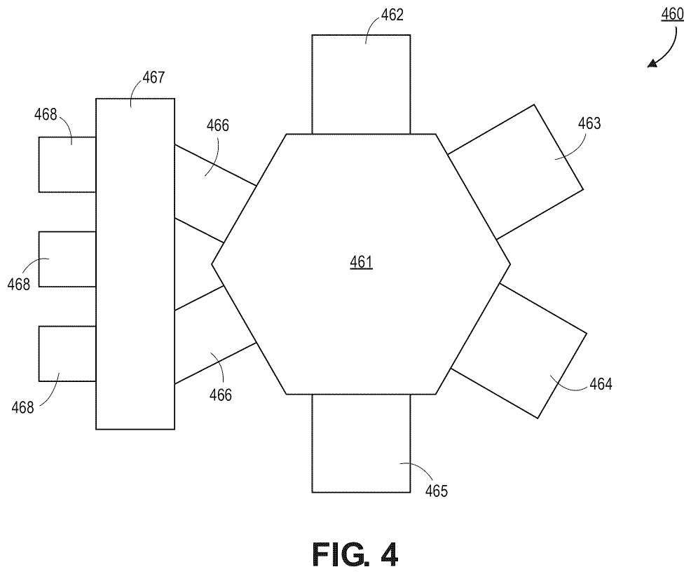

Referring now to FIG. 4, a plan view illustration of a processing tool 460 that is used to process substrates that include a bow mitigation layer is shown, in accordance with an embodiment. In an embodiment, the processing tool 460 may comprise a transfer chamber 461 that is coupled to a plurality of processing chambers 462-465. One or more of the processing chambers 462-465 may be suitable for depositing the bow mitigation layer on substrates, and one or more of the processing chambers 462-465 may be suitable for depositing one or more different device layers on the substrate opposite from the bow mitigation layer.

In a particular embodiment, processing chamber 462 may comprise a PECVD chamber with a high frequency RF source and a low frequency RF source that is used to deposit a bow reduction layer on the substrate. In an embodiment, the processing chamber 462 may be similar to the tool 250 described in greater detail herein. As such, the chamber 462 may be used to produce bow reduction layers that include a compressive stress with a magnitude of 2.0 GPa or higher. In an embodiment, the processing tool 460 may further comprise one or more load locks 466 to couple the vacuum environment of the transfer chamber 461 to a factory interface (FI) 467. The FI 467 may receive one or more substrate carriers 468, such as front opening unified pods (FOUPS) or the like.

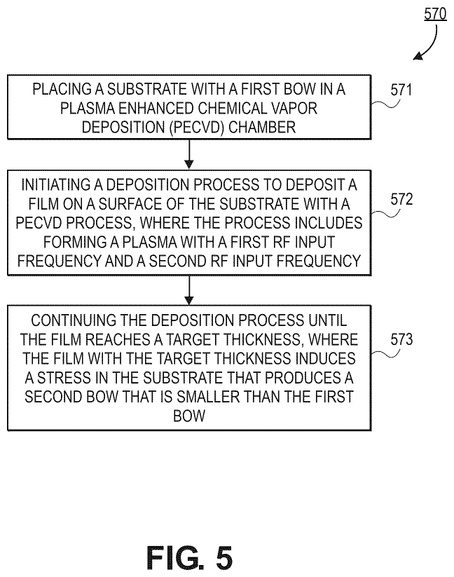

Referring now to FIG. 5, a flow diagram that depicts a process 570 for forming a compressive layer on the backside of a substrate is shown, in accordance with an embodiment. In an embodiment, the backside compressive layer may be similar to any of the backside compressive layers described in greater detail herein. In an embodiment, the process 570 may begin with operation 571, which comprises placing a substrate with a first bow in a PECVD chamber. In an embodiment, the first bow may be caused by the deposition of one or more device layers on a surface of the substrate. In some embodiments, the one or more device layers may induce a tensile stress in the substrate that results in a bow with a bowl shape on the surface with the one or more device layers. For example, the one or more device layers may be used to form a memory device or the like.

In an embodiment, the process 570 may continue with operation 572, which comprises initiating a deposition process to deposit a film on a surface of the substrate with a PECVD process. In an embodiment, the PECVD process may include forming a plasma with a first RF input frequency and a second RF input frequency. The first RF input frequency may be higher than the second RF input frequency. For example, the first RF input frequency may be approximately 20 MHz or higher, and the second RF input frequency may be approximately 500 kHz or lower. In an embodiment, the processing conditions of the PECVD process may be similar to any of the processing conditions described in greater detail herein. For example, the pressure may be between approximately 2 torr and approximately 6 torr, a temperature of the substrate may be approximately 400° C. or higher, the high frequency RF input may have a power that is between approximately 100 W and approximately 1,500 W, and the low frequency RF input may have a power that is between approximately 100 W and approximately 300 W. In an embodiment, the processing conditions may be chosen in order to deposit a film with a magnitude of compressive stress that is approximately 2.0 GPa or higher, approximately 2.5 GPa or higher, or approximately 3.0 GPa or higher.

In an embodiment, the film may comprise any suitable compressive layer, such as silicon nitride, boron nitride, silicon boron nitride, a carbon-based material, or the like. In a particular embodiment where a silicon nitride compressive layer is formed, the gas flow into the PECVD chamber may comprise one or more of NH₃, N₂, Ar, or SiH₄.

In an embodiment, the process 570 may continue with operation 573, which comprises continuing the deposition process until the film reaches a target thickness. In an embodiment, the target thickness results in the film inducing a stress in the substrate that produces a second bow. In an embodiment, the second bow is smaller than the first bow. That is, the film may result in a decrease in the bow. In some embodiments, the decrease in the bow may include substantially eliminating the bow of the substrate.

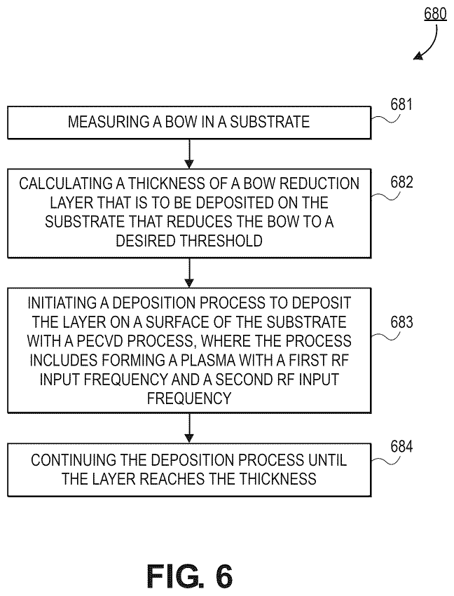

Referring now to FIG. 6, flow diagram that depicts a process 680 for forming a compressive layer on the backside of a substrate is shown, in accordance with an embodiment. In an embodiment, the backside compressive layer may be similar to any of the compressive layers described in greater detail herein. In an embodiment, the process 680 may begin with operation 681, which comprises measuring a bow in a substrate. In an embodiment, the amount of bow in the substrate may be measured with any suitable process, such as a capacitive measurement, laser sensing, profilometry, or the like.

In an embodiment, the process 680 may continue with operation 682, which comprises calculating a thickness of a bow reduction layer that is to be deposited on the substrate that reduces the bow to a desired threshold. In an embodiment, the calculation may be implemented by a processor or other computation device that is able to model the response of the substrate to various amounts of induced stress. In some embodiments, the desired threshold may be so that there is substantially no bow in the substrate. Other embodiments may include a threshold amount of bow that enables subsequent chucking of the substrate for further processing. In an embodiment, the bow may originally be 500 μm or more, 750 μm or more, or 1,000 μm or more, and after the desired threshold of the bow may be 500 μm or less, 250 μm or less, or 100 μm or less.

In an embodiment, the process 680 may continue with operation 683, which comprises initiating a deposition process to deposit a film on a surface of the substrate with a PECVD process. In an embodiment, the PECVD process may include forming a plasma with a first RF input frequency and a second RF input frequency. The first RF input frequency may be higher than the second RF input frequency. For example, the first RF input frequency may be approximately 20 MHz or higher, and the second RF input frequency may be approximately 500 kHz or lower. In an embodiment, the processing conditions of the PECVD process may be similar to any of the processing conditions described in greater detail herein. For example, one or more processing conditions may be similar to any of the conditions described with respect to operation 572 described above.

In an embodiment, the film may comprise any suitable compressive layer, such as silicon nitride, boron nitride, silicon boron nitride, a carbon-based material, or the like. In a particular embodiment where a silicon nitride compressive layer is formed, the gas flow into the PECVD chamber may comprise one or more of NH₃, N₂, Ar, or SiH₄.

In an embodiment, the process 680 may continue with operation 684, which comprises continuing the deposition process until the film reaches the thickness. In some embodiments, the thickness of the film may be up to approximately 1.0 μm. Though, thicker films may also be used in some embodiments.

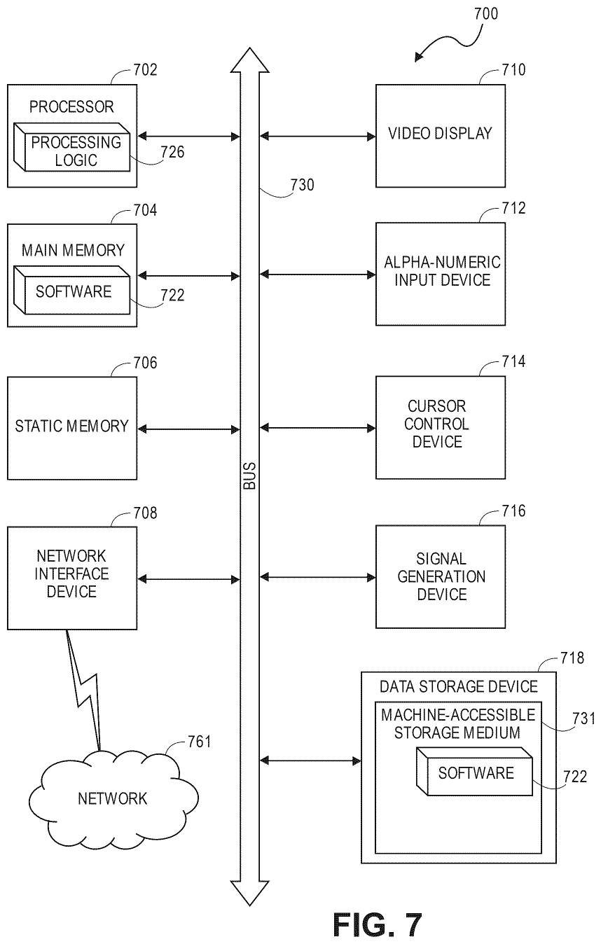

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 731 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 761 via the system network interface device 708. In an embodiment, the network interface device 708 may operate using RF coupling, optical coupling, acoustic coupling, or inductive coupling.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method, comprising:
initiating a deposition process to deposit a layer on a surface of a substrate with a first bow, wherein the deposition process is a plasma enhanced chemical vapor deposition (PECVD) process that comprises forming a plasma with a first RF input frequency and a second RF input frequency; and
continuing the deposition process until the layer reaches a target thickness, and wherein the layer with the target thickness induces a stress in the substrate that changes the first bow to a second bow that is smaller than the first bow.

2. The method of claim 1, wherein the first RF input frequency is higher than the second RF input frequency.

3. The method of claim 2, wherein the first RF input frequency is 20 MHz or higher, and wherein the second RF input frequency is 500 kHz or less.

4. The method of claim 1, wherein the layer comprises a silicon nitride composition.

5. The method of claim 4, wherein a process gas for the deposition process comprises one or more of NH₃, N₂, Ar, or SiH₄.

6. The method of claim 1, wherein a temperature of the substrate during the deposition process is 400° C. or higher.

7. The method of claim 1, wherein a pressure in a chamber used for the deposition process is between 2 torr and 6 torr.

8. The method of claim 1, wherein the layer comprises a compressive stress with a magnitude of approximately 2.0 GPa or higher.

9. The method of claim 1, wherein the layer comprises boron nitride, silicon boron nitride, or a carbon material.

10. The method of claim 1, wherein a thickness of the layer is up to 1.0 μm.

11. A method, comprising:
measuring a bow of a substrate;
calculating a thickness of a layer that is to be deposited on the substrate that reduces the bow to a desired threshold;
initiating a deposition process to deposit the layer on a surface of the substrate with a plasma enhanced chemical vapor deposition (PECVD) process, wherein the PECVD process comprises forming a plasma with a first RF input frequency and a second RF input frequency; and
continuing the deposition process until the layer reaches the thickness.

12. The method of claim 11, wherein the first RF input frequency is 20 MHz or higher, and wherein the second RF input frequency is 500 kHz or less.

13. The method of claim 11, wherein the layer comprises a silicon nitride composition.

14. The method of claim 11, wherein the bow of the substrate is up to 1,000 μm.

15. The method of claim 14, wherein the desired threshold is 500 μm or less.

16. The method of claim 11, wherein the layer comprises a compressive stress with a magnitude of approximately 2.0 GPa or higher.

17. The method of claim 11, wherein the layer comprises boron nitride, silicon boron nitride, or a carbon material.

18. A method, comprising:
depositing one or more device layers on a first surface of a substrate, wherein the one or more device layers induce a tensile stress on the substrate that produces a substrate bow; and
depositing a compressive silicon nitride layer on a second surface of the substrate with a plasma enhanced chemical vapor deposition (PECVD) process that comprises forming a plasma with a first RF input frequency and a second RF input frequency, wherein the compressive silicon nitride layer induces a compressive stress on the substrate that reduces the substrate bow.

19. The method of claim 18, wherein the compressive stress of the silicon nitride layer has a magnitude of approximately 2.0 GPa or higher.

20. The method of claim 18, wherein the first RF input frequency is 20 MHz or higher, and wherein the second RF input frequency is 500 kHz or less.
